(19) United States
(12) Patent Application Publication
(10) Pub. No.: US 2010/0181614 A1
(43) Pub. Date: Jul. 22, 2010

(54) SEMICONDUCTOR DEVICE AND METHOD OF MANUFACTURING THE SAME

(75) Inventor: Kazuhiro NOJIMA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/689,778

(22) Filed: Jan. 19, 2010

(30) Foreign Application Priority Data
Jan. 20, 2009 (JP) 2009-010372

(51) Int. Cl. H01L 29/78; H01L 21/28

(52) U.S. Cl. 257/329; 438/585; 257/E29.262; 257/E21.19

(57) ABSTRACT

A semiconductor device includes a semiconductor pillar, an insulator, and an electrode. The semiconductor pillar has a semiconductor portion outwardly extending. The insulator extends along the semiconductor pillar. The insulator has an insulating portion outwardly extending along the semiconductor portion. The electrode extends along the insulator. The insulator is between the semiconductor pillar and the electrode. The electrode has an electrode portion overlapping the insulating portion in plain view. The electrode portion is under the insulating portion.

### BACKGROUND OF THE INVENTION

1. Field of the Invention

The present invention relates to a semiconductor device and a method of manufacturing the same.

Priority is claimed on Japanese Patent Application No. 2009-010372, filed Jan. 20, 2009, the content of which is incorporated herein by reference.

2. Description of the Related Art

Recently, semiconductor chips have been smaller and smaller in size to reduce costs. For example, a DRAM (Dynamic Random Access Memory) realizing the 4F2 memory cell size (F denotes a design rule) by using a vertical MOS transistor (3D pillar-type MOS transistor) has been proposed.

Gate electrodes of such a vertical MOS transistor with a 4F2 memory cell size are formed by etching back. However, uneven etching causes a fluctuation in the gate length of the vertical MOS transistor. Consequently, the transistor characteristics of each vertical MOS transistor greatly fluctuate, thereby degrading their yield.

As an example of a vertical MOS transistor, Japanese Patent, Laid-Open Publication No. 2007-201454 discloses a semiconductor device including a conductive structure, a first insulating film, and a first conductive film pattern.

The conductive structure includes first to third portions. The second portion is disposed on the first portion and extends toward a first direction perpendicular to the plane of paper. The second portion is separated from another second portion in a second direction perpendicular to the first direction. The third portion is disposed on the second portion and is separated from another third portion in the first and second directions. The first insulating film covers sidewalls of the second portion. The first conductive film pattern covers the first insulating film.

As another example of a vertical MOS transistor, Japanese Patent, Laid-Open Publication No. H10-326879 discloses a semiconductor device including at least two cells each including a vertical MOSFET and a capacitor on the vertical MOSFET. The vertical MOSFET includes a source, a drain, and a gate. The capacitor includes first and second electrodes. The source of one cell is connected to that of an adjacent cell.

Regarding the above related arts, there have been demands for a semiconductor device and a method of manufacturing the same for achieving a smaller fluctuation in the gate length of a vertical MOS transistor to decrease a fluctuation in transistor characteristics.

### SUMMARY

In one embodiment, a semiconductor device includes a semiconductor pillar, an insulator, and an electrode. The semiconductor pillar has a semiconductor portion outwardly extending. The insulator extends along the semiconductor pillar. The insulator has an insulating portion outwardly extending along the semiconductor portion. The electrode extends along the insulator. The insulator is between the semiconductor pillar and the electrode. The electrode has an electrode portion overlapping the insulating portion in plain view. The electrode portion is under the insulating portion.

In another embodiment, a semiconductor device includes a plurality of semiconductor pillars, a plurality of insulators, and an electrode. Each of the plurality of semiconductor pillars has a semiconductor portion outwardly extending. Each of the plurality of insulators extends along corresponding one of the plurality of semiconductor pillars. Each of the plurality of insulators has an insulating portion outwardly extending along the semiconductor portion of the corresponding one of the plurality of semiconductor pillars. The electrode extends along the plurality of insulators. Each of the plurality of insulators is between the corresponding one of the plurality of semiconductor pillars and the electrode. The electrode has a plurality of electrode portions each overlapping the insulating portion of corresponding one of the plurality of insulators in plain view. Each of the plurality of electrode portions is under the insulating portion of the corresponding one of the plurality of insulators.

In still another embodiment, a method of manufacturing a semiconductor device includes the following processes. A semiconductor pillar having a semiconductor portion outwardly extending is formed. Then, an insulator extending along the semiconductor pillar is formed. The insulator has an insulating portion outwardly extending along the semiconductor portion. Then, an electrode extending along the insulator is formed. The insulator is between the semiconductor pillar and the electrode. The insulator insulates the electrode from the semiconductor pillar. The electrode has an electrode portion overlapping the insulating portion in plain view. The electrode portion is under the insulating portion.

Accordingly, a fluctuation in the gate length can be prevented, thereby preventing a fluctuation in the transistor characteristics of the vertical MOS transistor.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plane view illustrating 4F2 memory cells of a semiconductor device according to a first embodiment of the present invention;

FIG. 1B is a cross-sectional view taken along a line A-A′ shown in FIG. 1A;

FIGS. 2 to 11 cross-sectional views indicative of a process flow illustrating a method of manufacturing a vertical MOS transistor of the semiconductor device according to the first embodiment;

FIGS. 12 and 13 are cross-sectional views illustrating examples of vertical MOS transistors when etching back is unevenly carried out;

FIG. 14A is a plane view illustrating a comparison example of 4F2 memory cells;

FIG. 14B is a cross-sectional view taken along a line B-B′ shown in FIG. 14A; and

FIGS. 15 to 17 are cross-sectional views illustrating comparison examples of vertical MOS transistors.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

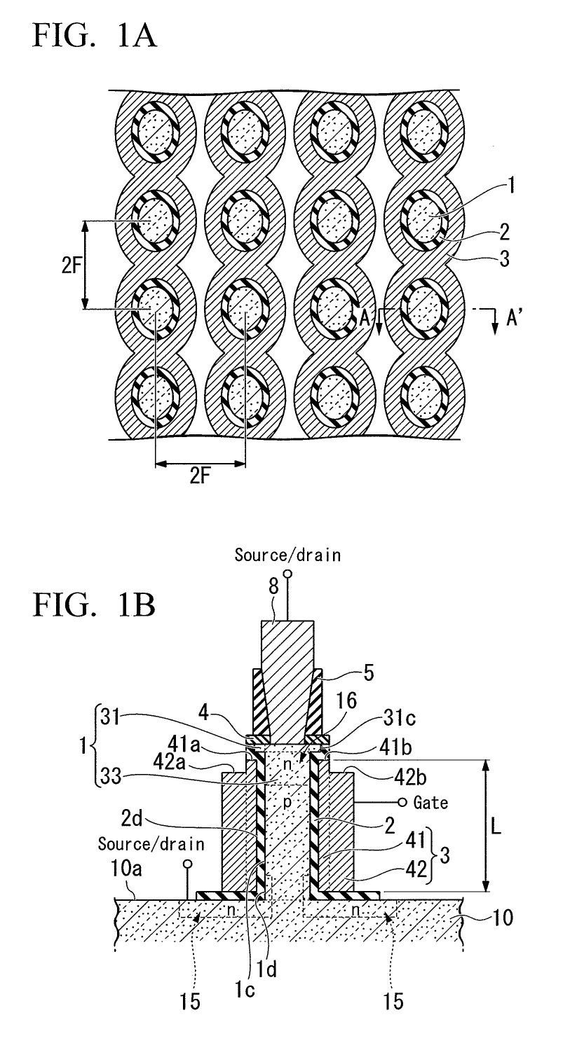

FIG. 1A is a plane view illustrating 4F2 memory cells of a semiconductor device according to a first embodiment of the present invention. FIG. 1B is a cross-sectional view taken along a line A-A′ shown in FIG. 1A.

As shown in FIG. 1A, the semiconductor device according to the first embodiment includes 4F2 memory cells including: pillars 1; first insulating films 2 each surrounding corresponding one of the pillars 1; and electrodes 3 each surrounding the first insulating films 2 while connecting the pillars 1 aligned in a straight line.

The pillars 1 are arranged in a grid and are substantially ellipses having the different horizontal-to-vertical ratios. The centers of the pillars 1 are separated by 2F (F is a design rule) both in the horizontal and vertical directions. A vertical MOS transistor is formed at each of the pillars 1.

As shown in FIG. 1B, the vertical MOS transistor includes: a substrate (semiconductor substrate) 10; the pillar 1 protruding from the substrate 10; impurity diffusion regions 15 and 16 on the bottom and top sides of the pillar 1, respectively; the first insulating film 2 covering a side surface of the pillar 1; and the electrode 3 covering the first insulating film 2. A contact plug 8 is connected to the top surface of the pillar 1. An insulating film 5 covers a side surface of the contact plug 8.

For example, an n-type impurity is diffused in the impurity diffusion regions 15 and 16. The impurity diffusion region 15 is connected to a power source. The impurity diffusion region 16 is connected to another power source through the contact plug 8.

For example, a p-type impurity is doped in the pillar 1. The electrode 3 is connected to a gate power source. Thus, the pillar 1 functions as a channel of the vertical MOS transistor.

The pillar 1 protrudes from the substrate 10. The pillar 1 has a large-diameter portion 31 on the top side of the pillar 1 and a small-diameter portion 33 under the large-diameter portion 31. Accordingly, a periphery 1c of the small-diameter portion 33 is inside a periphery 31c of the large-diameter portion 31 in plain view (i.e., when viewed in an extending direction of the pillar 1), thereby forming a recess 1d.

Although it is explained in the first embodiment that the pillar 1 is elliptical when viewed in the extending direction of the pillar 1, the pillar 1 may be circular, polygonal, or the like.

As will be explained in detail layer, the recess 1d is formed by etching a side surface of a pillar silicon substrate with a uniform thickness. The first insulating film 2 fills the recess 1d.

The electrode 3 includes first and second cylinders 41 and 42. The first cylinder 41 covers the side surface 1c of the pillar 1. The second cylinder 42 covers the first cylinder 42.

As will be explained in detail layer, the first and second cylinders 41 and 42 are formed by an electrode material film for forming the electrode 3 being etched. Therefore, the first and second cylinders 41 and 42 are made of the same material and integrated with each other.

The first insulating film 2 fills the recess 1d and forms another recess 2d having a level smaller than that of the recess 1d. The level of the recess 1d is measured from the upper surface of the first insulating layer 2 covering the substrate 10 to the lower surface of the large-diameter portion 31. The level of the recess 2d is measured from the upper surface of the first insulating layer 2 covering the substrate 10 to a top surface 41a or 41b of the first cylinder 41 that will be explained later.

The first cylinder 41 covers the side surface 1c of the pillar 1 through the first insulating film 2 so as to fill the recess 2d. Accordingly, the gate length of the vertical MOS transistor is uniquely defined by the level of the recess 2d, thereby achieving stable transistor characteristics.

Top surfaces 42a and 42b of the second cylinder 42 are positioned lower than top surfaces 41a and 41b of the first cylinder 41. Accordingly, a voltage is not applied from the second cylinder 42 to the pillar 1 through the first insulating film 2, thereby keeping the transistor characteristics stable.

The second cylinder 42 surrounds the first cylinder 41, thereby making the electrode 3 thicker. Additionally, a voltage from the power source to the electrode 3 can be kept constant, and a voltage can be evenly applied to the side surface 1c of the pillar 1. Moreover, the gate resistance can be reduced.

The first insulating film 2 on the upper substrate 10 around the pillar 1 insulates the substrate 10 from the electrode 3. The electrode 3 is made of, for example, polysilicon formed by in-situ doping phosphorus (P) at a concentration of 1×E²⁰/cm³, a metal such as tungsten (W), titanium nitride (TiN), silicide such as cobalt silicide (CoSi₂), or the like.

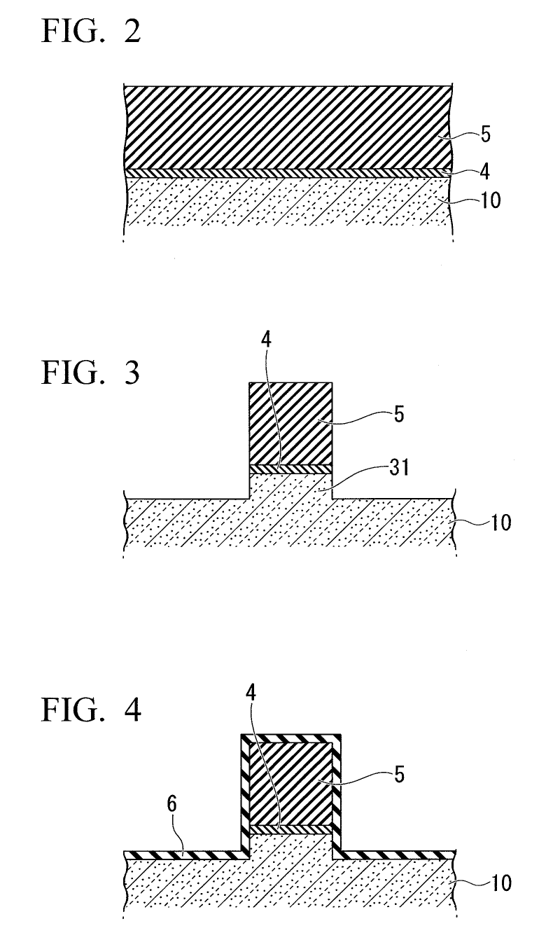

FIGS. 2 to 11 are cross-sectional views indicative of a process flow illustrating a method of manufacturing the vertical MOS transistor included in the semiconductor device according to the first embodiment.

The method includes: a pillar-base formation process of forming a pillar base 32 for forming the pillar 1; a pillar formation process of forming the pillar 1; a first insulating film formation process of forming the first insulating film 2; and an electrode formation process of forming the electrode 3.

In the pillar base formation process, the second and third insulating films 4 and 5 are formed in this order over the substrate 10 as shown in FIG. 2. The substrate 10 is a semiconductor substrate, such as silicon substrate, into which a p-type or n-type impurity may be doped.

The second insulating film 4 is, for example, a silicon oxide film that can be formed by, for example, thermally oxidizing a surface of the silicon substrate 10 or by CVD. The third insulating film 5 is, for example, a silicon nitride film that can be formed by, for example, CVD.

Then, the large-diameter portion 31 is formed by photolithography and etching as shown in FIG. 3. Specifically, a resist material is applied over the third insulating film 5 and exposed using a mask. Then, the exposed portion is removed using a solution to form a resist mask.

Then, the exposed second and third insulating films 4 and 5 are etched back using the resist mask to form a hard mask (nitride film) including the second and third insulating films 4 and 5.

Then, the upper surface of the substrate 10 is anisotropically dry etched using the hard mask as shown in FIG. 3. The resist mask may be removed before the etching process or simultaneously removed in the etching process.

Then, a fourth insulating film 6 is formed so as to cover the entire surface as shown in FIG. 4. The fourth insulating film 6 is, for example, a silicon oxide film that can be formed by CVD.

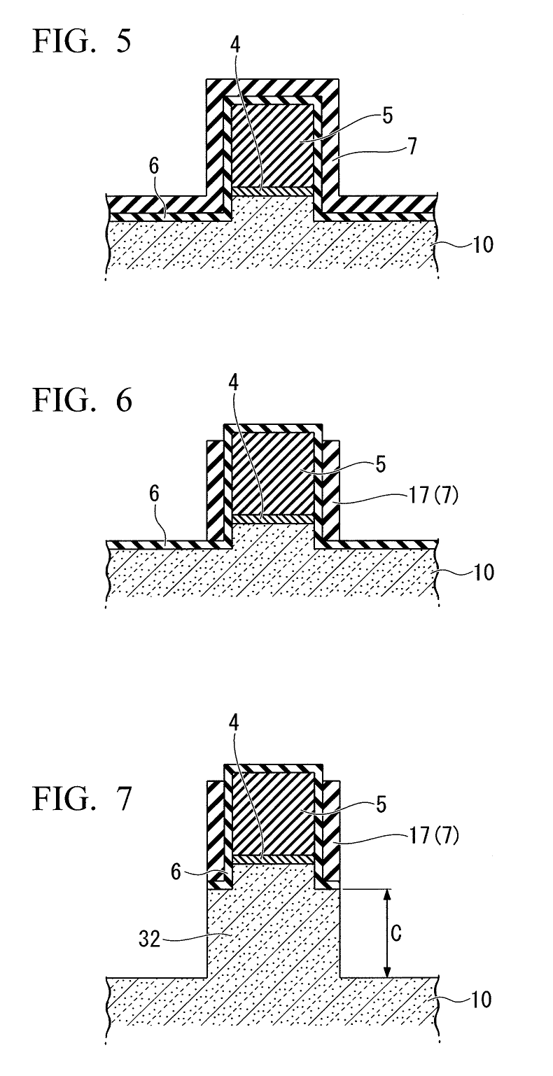

Then, a fifth insulating film 7 is formed so as to cover the fourth insulating film 6 as shown in FIG. 5. The fifth insulating film 7 is, for example, a silicon nitride film that can be formed by CVD.

Then, the fifth insulating film 7 is etched back by anisotropic dry etching to form a sidewall 17 as shown in FIG. 6. Then, the fourth insulating film 6 on the substrate 10 is anisotropically etched.

Then, the substrate 10 is anisotropically etched using a hard mask including the sidewall 17, and the third and fourth insulating films 5 and 6 to form the pillar base 32 having a level C.

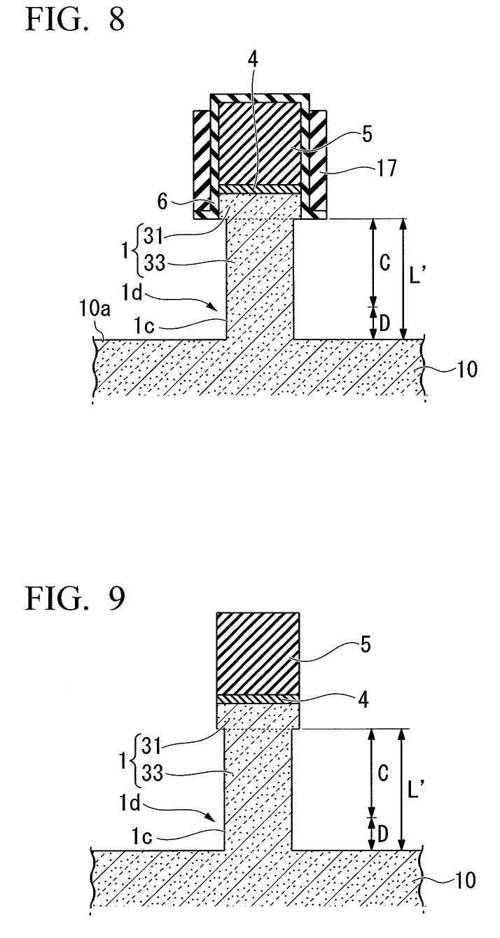

In the pillar formation process, the side surface of the pillar base 32 and the substrate 10 which are not covered by the insulating film is isotropically wet-etched by a depth D to form the pillar 1, as shown in FIG. 8.

In this case, the substrate 10 is etched by the depth D. Consequently, a level of the exposed pillar base 32 is L′ (=C+D), and the diameter of the pillar base 32 decreases by 2D. However, the top side of the pillar 1 is covered by the hard mask including the sidewall 17, and the third and fourth insulating films 5 and 6, and therefore the shape of the top side is maintained.

Thus, the large-diameter portion 31 remains on the top side of the pillar 1, and the small-diameter portion 33 is formed under the large-diameter portion 31. Accordingly, the recess 1d is formed on the side surface 1c of the pillar 1 due to the difference in the diameters of the portions 31 and 33.

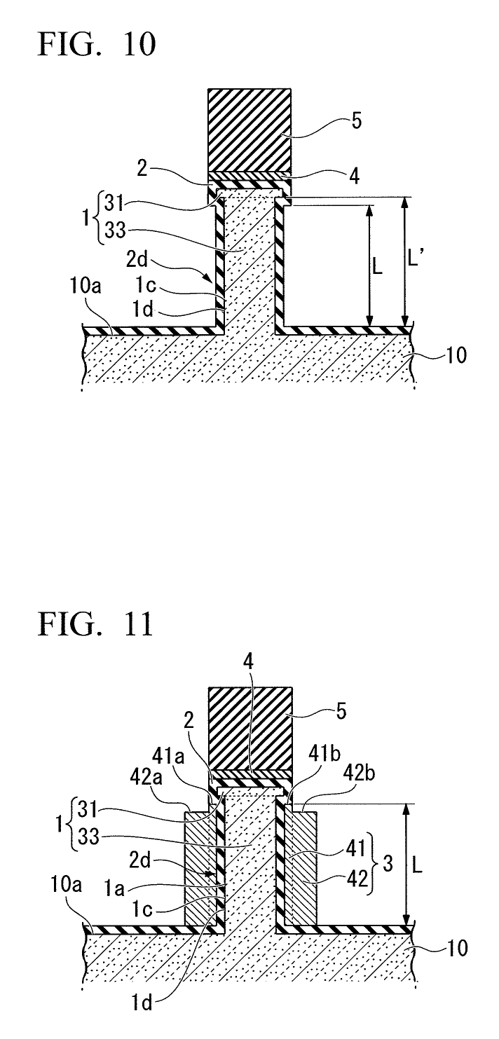

In the first insulating film formation process, the sidewall 17 and the fourth insulating film 6 are removed as shown in FIG. 9. Then, the first insulating film 2 is formed so as to cover the exposed surfaces of the substrate 10 and the pillar 1 as shown in FIG. 10.

The first insulating film 2 is, for example, a silicon oxide film that can be formed by thermally oxidizing the surface of the silicon substrate 10 or by CVD. By the first insulating film 2 filling the recess 1d, the other recess 2d is formed. A level L of the recess 2d is bit smaller than the level L′ of the recess 1d.

In the electrode formation process, an electrode material film for forming the electrode 3 is formed so as to cover the side surface of the pillar 1 covered by the first insulating film 2 and the upper surface of the substrate 10 covered by the first insulating film 2.

Then, the electric material film is anisotropically dry etched until the first insulating film 2 covering the upper surface of the substrate 10 is exposed, thus forming the electrode 3 as shown in FIG. 11.

The electrode 3 includes the first and second cylinders 41 and 42. The first cylinder 41 fills the recess 2d so as to cover the first insulating film 2. Accordingly, the level of the first cylinder 41 is uniquely defined by the level of the recess 2d.

The second cylinder 42 covers the first cylinder 41. The first and second cylinders 41 and 42 are made of the same electrode material, and therefore are integrated with each other.

According to the structure of the first and second cylinders 41 and 42, the top ends 41a and 41b of the first cylinder 41 have the same level even if the etching rate varies, thereby uniquely defining the gate length of the MOS transistor as the level L of the recess 2d, and therefore achieving stable transistor characteristics.

The top ends 42a and 42b of the second cylinder 42 are positioned lower than the top ends 41a and 41b of the first cylinder 41. Accordingly, a voltage is not applied from the second cylinder 42 to the pillar 1 through the first insulating film 2, thereby achieving the stable transistor characteristics.

The second cylinder 42 covers the first cylinder 41, thereby making the electrode 3 thicker. For this reason, a voltage from the power source to the electrode 3 can be kept constant, thereby enabling a voltage to be evenly applied to the side surface 1c of the pillar 1, and enabling the gate resistance to be reduced. The electrode 3 is insulated from the substrate 10 by the first insulating film 2 covering the substrate 10.

Then, the impurity diffusion regions 15 and 16 are formed on the top and bottom portions of the pillar 1, respectively. For example, an impurity, such as arsenic, is ion implanted at a concentration of 1×E¹⁵/cm² at energy of 10 KeV by plasma doping from both sides of the third insulating film 5 into the top portion of the pillar 1.

Although it has been explained above that the impurity diffusion regions 15 and 16 are formed after the electrode 3 is formed, the impurity diffusion region 15 may be formed after the pillar 1 is formed by wet etching. Additionally, the impurity diffusion region 16 may be formed by ion implantation when a contact hole for the contact plug 8 is formed as will be explained layer.

Finally, the contact plug 8 is formed so as to connect to the impurity diffusion region 16 after an inter-layer insulating film is formed so as to cover the upper portion of the pillar 1. Thus, the vertical MOS transistor as shown in FIG. 1B is formed.

Regarding the above method, the etching rate of the electrode material film varies depending on various conditions. For example, the etching rate of the electrode material film is smaller at a portion closer to the first insulating film 2, thereby causing the aforementioned etching back to be unevenly carried out.

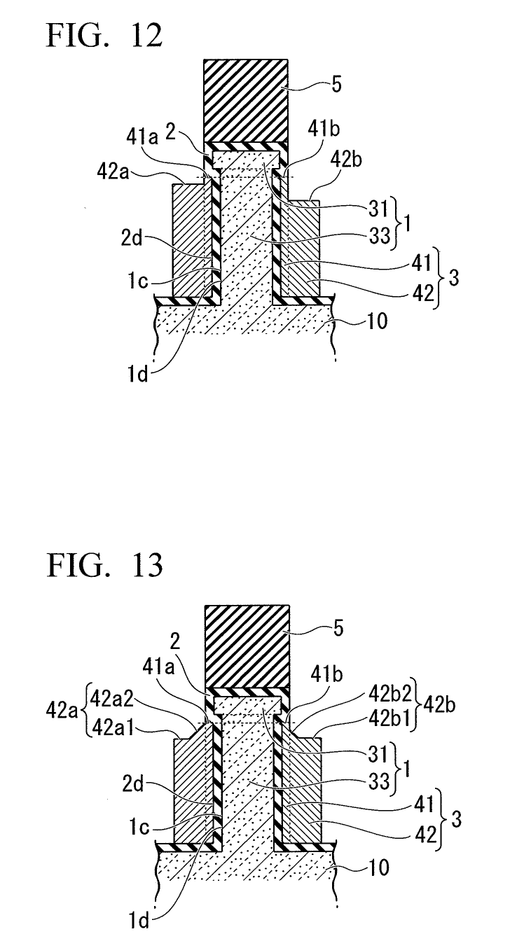

FIG. 12 is a cross-sectional view illustrating an example of a vertical MOS transistor when the etching back is unevenly carried out. In this case, the top ends 42a and 42b of the second cylinder 42 have different heights.

Even in this case, the first cylinder 41 is formed so as to fill the recess 2d and to cover the side surface 1c of the pillar 1 through the first insulating film 2. Accordingly, the top ends 41a and 41b of the first cylinder 41 have the same level, thereby uniquely defining the gate length of the vertical MOS transistor as the level L of the recess 2d, and therefore achieving stable transistor characteristics.

FIG. 13 is a cross-sectional view illustrating another example of a vertical MOS transistor when the etching back is unevenly carried out. In this case, the top ends 42a and 42b of the second cylinder 42 are sloped. The top end 42a includes a flat portion 42a1 and a sloped portion 42a2. The other top end 42b includes a flat portion 42b1 and a sloped portion 42b2. The angles of the sloped portions 42a2 and 42b2 are substantially the same. The sloped surface of the sloped portion 42a2 is larger than that of the sloped portion 42b2.

Even in this case, the first cylinder 41 is formed so as to fill the recess 2d and to cover the side surface 1c of the pillar 1 through the first insulating film 2. Accordingly, the top ends 41a and 41b of the first cylinder 41 have the same level, thereby uniquely defining the gate length of the vertical MOS transistor as the level L of the recess 2d, and therefore achieving stable transistor characteristics.

Although it has been explained above that the electrode 3 includes the first and second cylinders 41 and 42, the second cylinder 42 may not be formed if only the first cylinder 41 can achieve stable transistor characteristics.

As explained above, according to the semiconductor device of the first embodiment, a fluctuation in the gate length can be prevented, thereby preventing a fluctuation in the transistor characteristics of the vertical MOS transistor.

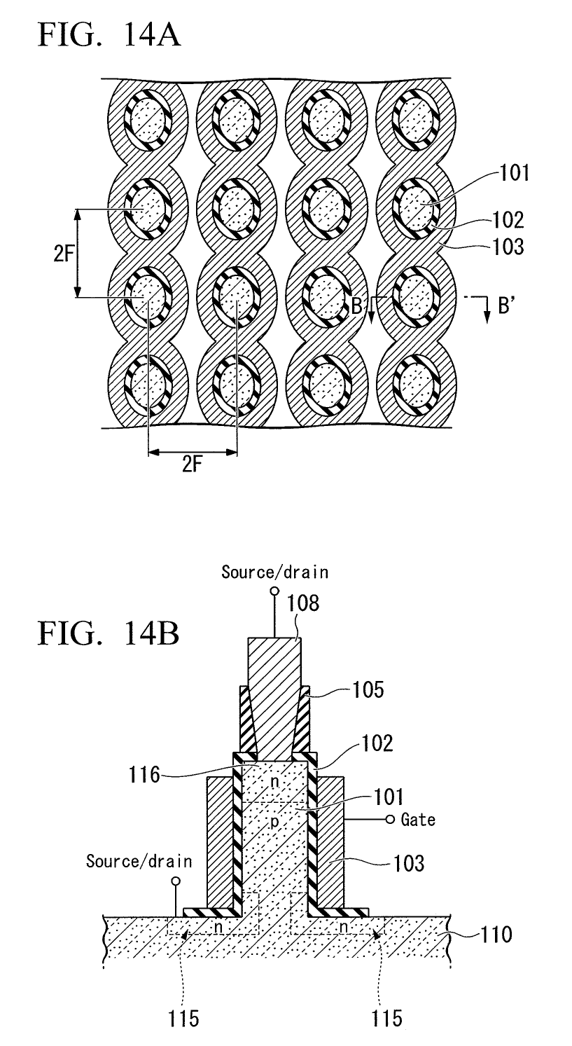

Hereinafter, comparison examples are explained. FIG. 14A is a plane view illustrating a comparison example of 4F2 memory cells (semiconductor device). FIG. 14B is a cross-sectional view taken along a line B-B′ shown in FIG. 14A.

As shown in FIG. 14A, the 4F2 memory cells include: pillars 101; first insulating films 102 each surrounding corresponding one of the pillars 101; and electrodes 103 each surrounding the first insulating films 102 while connecting the pillars 101 aligned in a straight line.

The pillars 101 are arranged in a grid and are substantially ellipses having a different horizontal-to-vertical ratio. The centers of the pillars 101 are distanced by 2F (F is a design rule) both in horizontal and vertical directions. A vertical MOS transistor is formed at each of the pillars 101.

The vertical MOS transistor shown in FIG. 14B includes: a substrate 110; the pillar 101 protruding from the substrate 110; impurity diffusion regions 115 and 116 on the bottom and top sides of the pillar 101, respectively; a gate oxide film 102 covering a side surface of the pillar 101; and a gate electrode 103 covering the gate oxide film 102. A contact plug 108 is connected to the top surface of the pillar 101. A nitride film 105 covers a side surface of the contact plug 108.

As shown in FIG. 14B, the lower impurity diffusion region 115 is connected to an S/D power source. The upper impurity diffusion region 116 is connected to another S/D power source through the contact plug 108. The gate electrode 103 is connected to a gate power source, thus forming the vertical MOS transistor.

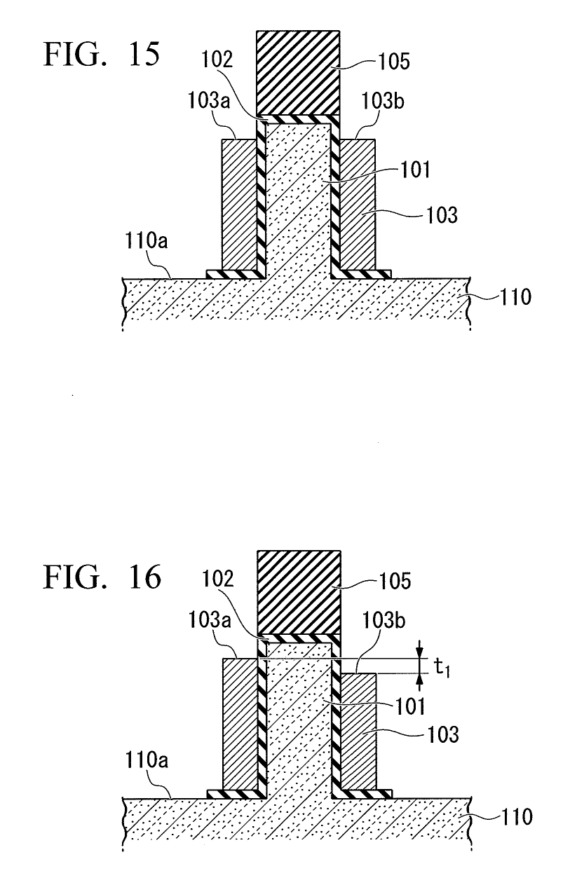

FIGS. 15 to 17 are cross-sectional views illustrating the gate electrode 103 of the vertical MOS transistor shown in FIG. 14B having been formed. When the gate electrode 103 is formed, a gate electrode material film having a predetermined thickness is formed by a known method so as to cover the pillar 101 and an upper surface 110a of the substrate 110.

Then, the gate electrode material film is evenly etched back by anisotropic dry etching from the top end 101a of the pillar 101 down to the level of the upper surface 110a of the substrate 110, thus forming the cylindrical gate electrode 103 surrounding the gate oxide film 102.

In many cases, top ends 103a and 103b of the gate electrodes 103 have the same level. In these cases, a fluctuation in the transistor characteristics of the vertical MOS transistor is small.

However, the etching rate of the electrode material film varies depending on various conditions. For example, the etching rate of the electrode material film is smaller at a portion closer to the gate oxide film 102, thereby causing uneven etching back.

FIG. 16 illustrates a case where the etching back has been unevenly carried out, and therefore the top ends 103a and 103b of the gate electrode 103 have different levels.

The top end 103b is positioned lower by a value of t₁ than the top end 103a. In this case, the gate length differs between the top ends 103a and 103b, thereby causing a large fluctuation in the vertical MOS transistor.

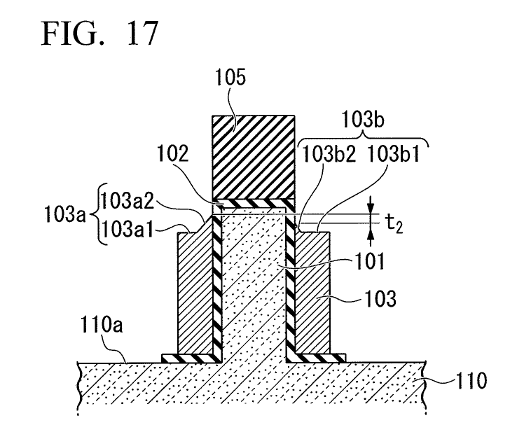

FIG. 17 illustrates another case where the etching back has been unevenly carried out, and therefore the top ends 103a and 103b of the gate electrode 103 have sloped portions.

The top end 103a includes a flat portion 103a1 and a sloped portion 103a2. The other top end 103b includes a flat portion 103b1 and a sloped portion 103b2. The angles of the sloped portions 103a2 and 103b2 are substantially the same. The sloped surface of the sloped portion 103a2 is larger than that of the sloped portion 103b2.

For this reason, the top end 103b is positioned lower by a value of t₂ than the top end 103a. Also in this case, the gate length differs between the top ends 103a and 103b, thereby causing a large fluctuation in the vertical MOS transistor.

As explained above, if the etching rate of the gate electrode material film of the vertical MOS transistor varies, the length of the gate electrode varies. Consequently, the gate length of the vertical MOS transistor varies, thereby causing a larger fluctuation in the transistor characteristics.

The present invention is applicable to semiconductor device manufacturing industries.

It is apparent that the present invention is not limited to the above embodiments, but may be modified and changed without departing from the scope and spirit of the invention.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

What is claimed is:

1. A semiconductor device comprising:
a semiconductor pillar having a semiconductor portion outwardly extending;
an insulator extending along the semiconductor pillar, the insulator having an insulating portion outwardly extending along the semiconductor portion; and
an electrode extending along the insulator, the insulator being between the semiconductor pillar and the electrode, the electrode having an electrode portion overlapping the insulating portion in plain view, and the electrode portion being under the insulating portion.

2. The semiconductor device according to claim 1, wherein the insulator insulates the electrode from the semiconductor pillar.

3. The semiconductor device according to claim 1, wherein
the insulator surrounds the semiconductor pillar in plain view, and
the electrode surrounds the insulator in plain view.

4. The semiconductor device according to claim 1, wherein a boundary between insulating portion and the electrode portion has a first level that is substantially even.

5. The semiconductor device according to claim 4, wherein a boundary between the semiconductor portion and the insulating portion has a second level that is substantially even, the second level being greater than the first level.

6. The semiconductor device according to claim 1, wherein the semiconductor pillar has first to third regions, the first region being adjacent to a top surface of the semiconductor pillar, the second region being adjacent to a bottom surface of the semiconductor pillar, the third region being other than the first and second regions, an n-type impurity being implanted into the first and second regions, and a p-type impurity being implanted into the third region.

7. The semiconductor device according to claim 1, wherein the semiconductor pillar is elliptical when viewed in the extending direction.

8. A semiconductor device comprising:
a plurality of semiconductor pillars each having a semiconductor portion outwardly extending;
a plurality of insulators each extending along corresponding one of the plurality of semiconductor pillars, the plurality of insulators each having an insulating portion outwardly extending along the semiconductor portion of the corresponding one of the plurality of semiconductor pillars; and
an electrode extending along the plurality of insulators, the plurality of insulators each being between the corresponding one of the plurality of semiconductor pillars and the electrode, the electrode having a plurality of electrode portions each overlapping the insulating portion of corresponding one of the plurality of insulators in plain view, and the plurality of electrode portions each being under the insulating portion of the corresponding one of the plurality of insulators.

9. The semiconductor device according to claim 8, wherein the plurality of insulators each insulating the electrode from the corresponding one of the plurality of semiconductor pillars.

10. The semiconductor device according to claim 8, wherein
the plurality of insulators each surrounds the corresponding one of the plurality of semiconductor pillars in plain view, and
the electrode surrounds the plurality of insulators in plain view.

11. The semiconductor device according to claim 8, wherein a boundary between each of the plurality of electrode portions and the insulating portion of the corresponding one of the plurality of insulators has a first level that is substantially even.

12. The semiconductor device according to claim 11, wherein a boundary between the semiconductor portion of each of the plurality of semiconductor pillars and the insulating portion of the corresponding one of the insulators has a second level that is substantially even, the second level being greater than the first level.

13. The semiconductor device according to claim 8, wherein each one of the semiconductor pillars has first to third regions, the first and second regions being adjacent to top and bottom surfaces of the one of the semiconductor pillars, respectively, the third region being other than the first and second regions, an n-type impurity being implanted into the first and second regions, and a p-type impurity being implanted into the third region.

14. The semiconductor device according to claim 8, wherein each of the plurality of semiconductor pillars is elliptical in plain view.

15. The semiconductor device according to claim 8, wherein the plurality of semiconductor pillars is arranged in a grid at a predetermined pitch in plain view.

16. The semiconductor device according to claim 15, wherein the electrode surrounds the plurality of insulators aligned in a straight line.

17. A method of manufacturing a semiconductor device, comprising:
forming a semiconductor pillar having a semiconductor portion outwardly extending;
forming an insulator extending along the semiconductor pillar, the insulator having an insulating portion outwardly extending along the semiconductor portion; and
forming an electrode extending along the insulator, the insulator being between the semiconductor pillar and the electrode, the insulator insulating the electrode from the semiconductor pillar, the electrode having an electrode portion overlapping the insulating portion in plain view, and the electrode portion being under the insulating portion.

18. The semiconductor device according to claim 17, wherein
the insulator surrounds the semiconductor pillar in plain view, and
the electrode surrounds the insulator in plain view.

19. The method according to claim 17, wherein forming the semiconductor pillar comprising:
forming a semiconductor substrate having a pillar portion upwardly extending;
forming an insulating layer covering the pillar portion and the substrate;
dry etching the substrate while the insulating layer covers a side surface of the pillar portion; and
wet etching the substrate remaining under the pillar portion while the insulating layer covers the side surface.

20. The method according to claim 19, wherein forming the electrode comprising:
forming an electrode material film over the insulator covering the pillar portion and the substrate; and
dry etching the electrode material until the insulator covering the substrate is exposed.
